(19) United States
(12) Patent Application Publication
(10) Pub. No.: US 2019/0371737 A1
(43) Pub. Date: Dec. 5, 2019

(54) ELECTROMAGNETIC INTERFERENCE SHIELDING STRUCTURE AND SEMICONDUCTOR PACKAGE INCLUDING THE SAME

(71) Applicant: SAMSUNG ELECTRONICS CO., LTD., Suwon-si (KR)

(72) Inventors: Woon Chun KIM, Suwon-si (KR); Ji Hye SHIM, Suwon-Si (KR); Jun Heyoung PARK, Suwon-Si (KR)

(73) Assignee: SAMSUNG ELECTRONICS CO., LTD., Suwon-si (KR)

(21) Appl. No.: 16/161,797

(22) Filed: Oct. 16, 2018

(30) Foreign Application Priority Data
Jun. 1, 2018 (KR) 10-2018-0063419

(51) Int. Cl. H01L 23/552; H01L 21/56; H01L 23/31; H01L 23/58; H01L 23/00

(52) U.S. Cl. CPC H01L 23/552; H01L 21/56; H01L 23/3128; B82Y 30/00; H01L 24/45; H01L 24/48; H01L 2224/29001; H01L 23/585

(57) ABSTRACT

An electromagnetic interference shielding structure includes a base layer and an electromagnetic interference shielding layer disposed on the base layer. The electromagnetic shielding layer includes a plurality of porous conductor layers, each of the porous conductor layers has a plurality of openings, and the porous conductor layers are stacked on each other in a stacking direction. A semiconductor package includes the electromagnetic interference shielding structure.

### CROSS-REFERENCE TO RELATED APPLICATION(S)

This application claims benefit of priority to Korean Patent Application No. 10-2018-0063419 filed on Jun. 1, 2018 in the Korean Intellectual Property Office, the disclosure of which is incorporated herein by reference in its entirety.

### TECHNICAL FIELD

The present disclosure relates to an electromagnetic interference shielding structure and a semiconductor package including the same.

### BACKGROUND

As a new mobile communications era has been created in accordance with remarkable growth in the use of mobile devices such as smartphones, there have been large and small problems, not present in the past. There among, a particularly prominent problem is a problem of malfunctioning of a device caused by electromagnetic interference. Therefore, naturally, interest in electromagnetic interference shielding technology has increased.

As a device having a reduced thickness for the tactile sensation of a user, and a design having high specifications has been required, a semiconductor, an essential component, has been further thinned and miniaturized. As electromagnetic waves generated in components disposed without voids as described above interfere with each other, a malfunction problem has emerged.

In order to solve this problem, there has been an attempt to actively apply electromagnetic interference (EMI) shielding technology to information technology (IT) fields.

Recently, a shielding technology of forming a metal film for shielding electromagnetic interference has been used in a semiconductor package itself. However, in a case of performing a high-temperature process such as a reflow process for connecting solder, delamination of a shielding film may occur due to volume expansion of steam from water contained in the package.

### SUMMARY

An aspect of the present disclosure may provide an electromagnetic interference shielding structure having a porous structure capable of solving a delamination problem of a shielding film, adjusting a size and thickness of a pore, and being formed by a coating method, and a semiconductor package including the same.

According to an aspect of the present disclosure, an electromagnetic interference shielding layer having a porous maze structure may be provide by repeatedly forming a porous structure on a base layer in layers using a self-alignable nanoparticle coating solution.

According to an aspect of the present disclosure, an electromagnetic interference shielding structure may include:

a base layer and an electromagnetic interference shielding layer disposed on the base layer. The electromagnetic shielding layer may include a plurality of porous conductor layers, each of the porous conductor layers may have a plurality of openings, and the porous conductor layers may be stacked on each other in a stacking direction.

According to another aspect of the present disclosure, a semiconductor package may include: a connection member having redistribution layers; a semiconductor chip disposed on a connection member and having an active surface on which connection pads electrically connected to the redistribution layers are disposed and an inactive surface opposing the active surface; an encapsulant disposed on the connection member and encapsulating the semiconductor chip; and an electromagnetic interference shielding layer disposed on the encapsulant. The electromagnetic shielding layer may include a plurality of porous conductor layers, each of the porous conductor layers may have a plurality of openings, and the porous conductor layers may be stacked on each other in a stacking direction.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a block diagram schematically illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a printed circuit board and is ultimately mounted on a mainboard of an electronic device;

FIG. 6 is a schematic cross-sectional view illustrating a case in which a fan-in semiconductor package is embedded in a printed circuit board and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of an electromagnetic interference shielding structure;

FIG. 10 is a schematic plan view of the electromagnetic interference shielding structure of FIG. 9 when viewed from the top;

FIGS. 11A and 11B are schematic views illustrating an example of a manufacturing method of the electromagnetic interference shielding structure of FIG. 9;

FIG. 12 is a schematic cross-sectional view illustrating another example of the electromagnetic interference shielding structure;

FIG. 13 is a schematic plan view of the electromagnetic interference shielding structure of FIG. 12 when viewed from the top;

FIGS. 14A and 14B are schematic views illustrating an example of a manufacturing method of the electromagnetic interference shielding structure of FIG. 12;

FIG. 15 is a schematic cross-sectional view illustrating an example of a semiconductor package;

FIG. 16 is a schematic cross-sectional view illustrating another example of the semiconductor package;

FIG. 17 is a schematic cross-sectional view illustrating another example of the semiconductor package; and

FIG. 18 is a schematic cross-sectional view illustrating another example of the semiconductor package.

### DETAILED DESCRIPTION

Hereinafter, exemplary embodiments of the present disclosure will now be described in detail with reference to the accompanying drawings.

Hereinafter, exemplary embodiments in present disclosure will be described with reference to the accompanying drawings. In the accompanying drawings, shapes, sizes, and the like, of components may be exaggerated or shortened for clarity.

### Electronic Device

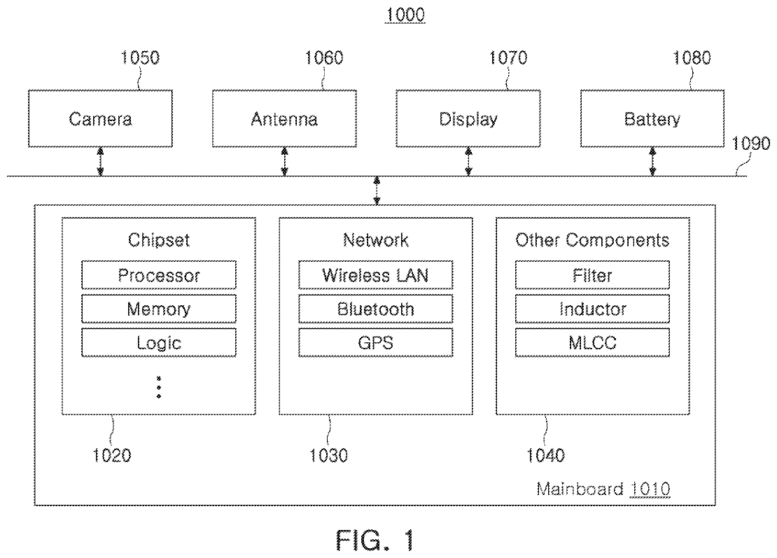

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be coupled to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. Further, these chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the above-mentioned protocols.

However, the network related components 1030 are not limited thereto, but may also include a variety of other wireless or wired standards or protocols. Further, the network related components 1030 may be combined with each other, together with the above-mentioned chip related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. Further, other components 1040 may be combined with each other, together with the chip related components 1020 and/or the network related components 1030.

Depending on a type of the electronic device 1000, the electronic device 1000 may include other components that may be or may not be physically and/or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may also be any other electronic device processing data.

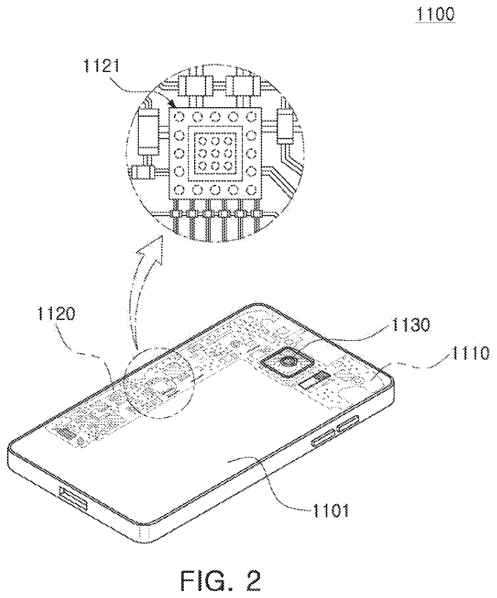

FIG. 2 is a schematic perspective view illustrating an example of an electronic device.

Referring to FIG. 2, a semiconductor package may be used for various purposes in the various electronic devices 1000 as described above. For example, a printed circuit board 1110 such as the mainboard, or the like, may be accommodated in a body 1101 of a smartphone 1100, and various components 1120 may be physically and/or electrically connected to the printed circuit board 1110 as described above. Further, another component that may be or may not be physically and/or electrically connected to the printed circuit board 1110, such as, a camera 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

### Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip.

Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

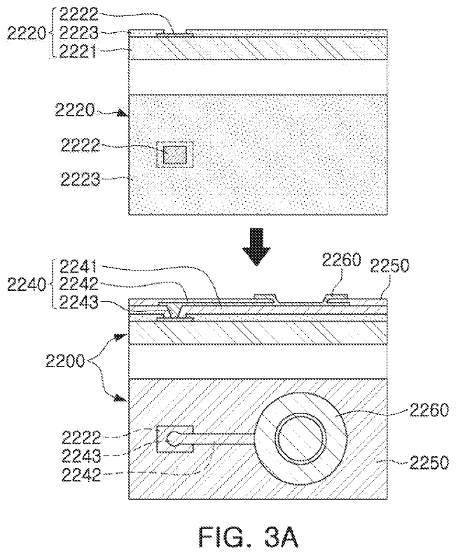

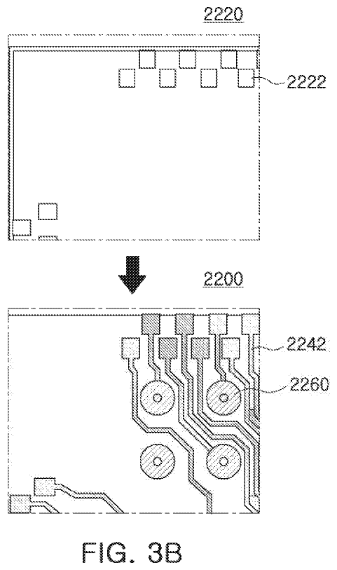

FIGS. 3A and 3B are schematic cross-sectional views illustrating states of a fan-in semiconductor package before and after being packaged.

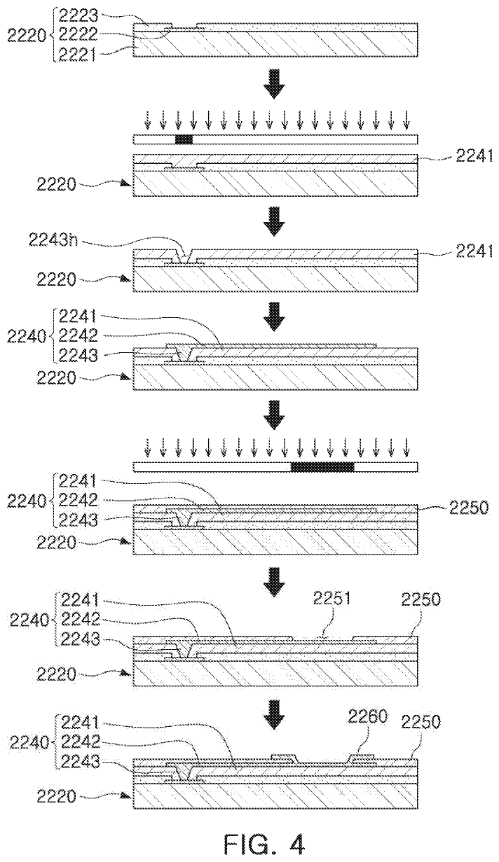

FIG. 4 is schematic cross-sectional views illustrating a packaging process of a fan-in semiconductor package.

Referring to FIGS. 3 and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation film 2223 such as an oxide film, a nitride film, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection structure 2240 may be formed depending on a size of the semiconductor chip 2220 on the semiconductor chip 2220 in order to redistribute the connection pads 2222. The connection structure 2240 may be formed by forming an insulating layer 2241 on the semiconductor chip 2220 using an insulating material such as a photoimageable dielectric (PID) resin, forming via holes 2243h opening the connection pads 2222, and then forming wiring patterns 2242 and vias 2243. Then, a passivation layer 2250 protecting the connection structure 2240 may be formed, an opening 2251 may be formed, and an underbump metal 2260, or the like, may be formed. That is, a fan-in semiconductor package 2200 including, for example, the semiconductor chip 2220, the connection structure 2240, the passivation layer 2250, and the underbump metal 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in electronic component package on the mainboard of the electronic device.

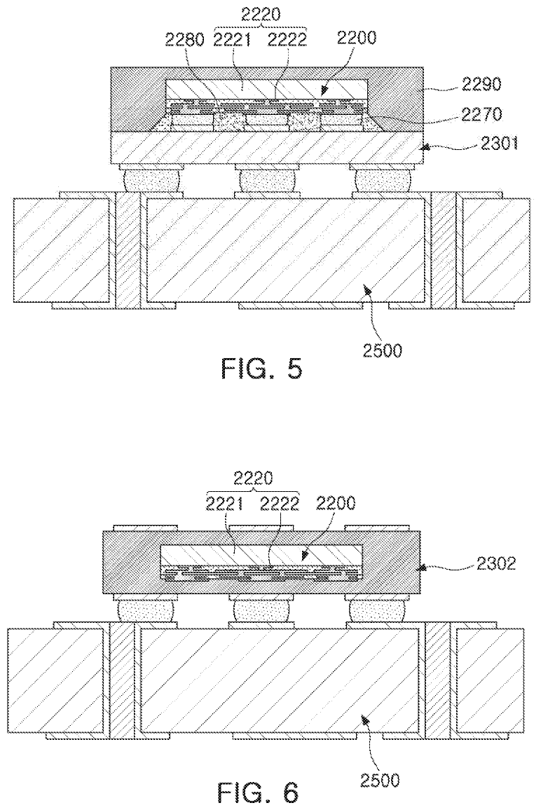

FIG. 5 is a schematic cross-sectional view illustrating a case in which a fan-in semiconductor package is mounted on a printed circuit board and is ultimately mounted on a mainboard of an electronic device.

FIG. 6 is a schematic cross-sectional view illustrating a case in which a fan-in semiconductor package is embedded in a printed circuit board and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a printed circuit board 2301, and the fan-in semiconductor package 2200 may be ultimately mounted on a mainboard 2500 of an electronic device in a state in which it is mounted on the printed circuit board 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate printed circuit board 2302, connection pads 2222, that is, I/O terminals, of the semiconductor chip 2220 may be redistributed by the printed circuit board 2302 in a state in which the fan-in semiconductor package 2200 is embedded in the printed circuit board 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate printed circuit board and be then mounted on the mainboard of the electronic device through a packaging process or may be mounted and used on the mainboard of the electronic device in a state in which it is embedded in the printed circuit board.

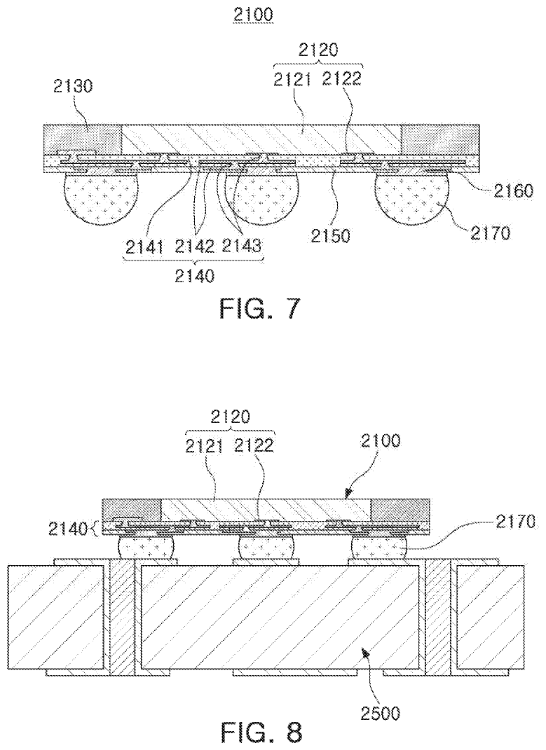

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection structure 2140. In this case, a passivation layer 2150 may further be formed on the connection structure 2140, and an underbump metal 2160 may further be formed in openings of the passivation layer 2150. Solder balls 2170 may further be formed on the underbump metal 2160. The semiconductor chip 2120 may be an integrated circuit (IC) including a body 2121, the connection pads 2122, and the like. The connection structure 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection structure formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection structure formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate printed circuit board, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection structure 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate printed circuit board, or the like.

As described above, since the fan-out semiconductor package may be mounted on the mainboard of the electronic device without using the separate printed circuit board, the fan-out semiconductor package may be implemented at a thickness lower than that of the fan-in semiconductor package using the printed circuit board. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to a package technology for mounting the semiconductor chip on the mainboard of the electronic device, or the like, as described above, and protecting the semiconductor chip from external impacts, and is a concept different from that of a printed circuit board (PCB) such as a printed circuit board having a scale, a purpose, and the like, different from those of the fan-out semiconductor package, and having the fan-in semiconductor package embedded therein.

Hereinafter, an electromagnetic interference shielding structure applicable for electromagnetic interference shielding of the semiconductor package will be described with reference to the accompanying drawings.

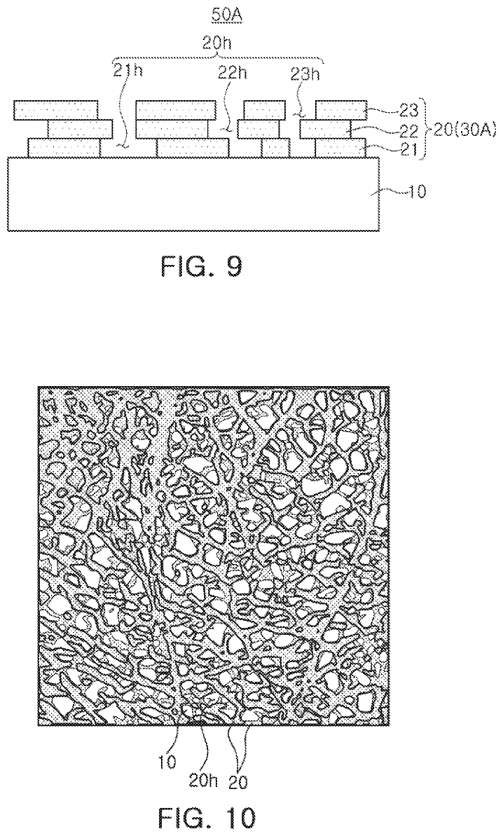

FIG. 9 is a schematic cross-sectional view illustrating an example of the electromagnetic interference shielding structure.

FIG. 10 is a schematic plan view of the electromagnetic interference shielding structure of FIG. 9 when viewed from the top.

Referring to FIGS. 9 and 10, an electromagnetic interference shielding structure 50A according to an exemplary embodiment in the present disclosure may include a base layer 10 and an electromagnetic interference shielding layer 30A disposed on the base layer 10. The electromagnetic interference shielding layer 30A may include a plurality of porous conductor layers 21, 22, and 23. The porous conductor layers 21, 22, and 23 may have porous structures having a plurality of openings 21h, 22h, and 23h, respectively. That is, each of the porous conductor layers 21, 22, and 23 may have a conductive mesh structure. A respective conductive mesh structure of the porous conductor layers 21, 22, and 23 may have a solid structure having respective openings 21h, 22h, or 23h distributed in a random manner in the solid structure. The porous conductor layers 21, 22, and 23 may be stacked to alternate with each other in a vertical direction. The porous conductor layers 21, 22, and 23 may be stacked to alternate with each other in the vertical direction to form a porous structure 20 having a plurality of pores 20h.

Meanwhile, as a new mobile communications era has been created in accordance with remarkable growth in the use of mobile devices such as smartphones, there have been large and small problems, which were not present in the past. There among, a particularly prominent problem is a problem of malfunctioning of a device caused by electromagnetic interference. Therefore, naturally, interest in electromagnetic interference shielding technology has increased. In an existing electromagnetic interference shielding technology, a metal can method of covering an entire substrate using a box-shaped metal shield to shield electromagnetic interference or a film method for shielding electromagnetic interference of a flexible printed circuit board (FPCB) has been used. However, since the entire substrate is covered at once in the metal can method, the metal can method has a limitation in decreasing a size and a thickness of a device, and in the film method, a polyimide film corresponding to a raw material needs to be refrigerated, and complicated processes such as shaping, mold manufacturing, film attaching, and the like, need to be manually performed, such that productivity, shielding uniformity, and stability may be deteriorated. Recently, shielding technologies using a sputtering method and a spraying method of covering an ultra-thin metal for shielding electromagnetic interference on a semiconductor package itself have been used. However, all methods have a limitation in solving a delamination problem of a shielding film at a high-temperature process.

On the contrary, in the electromagnetic interference shielding structure 50A according to the exemplary embodiment, the porous conductor layers 21, 22, and 23 having the conductive mesh structure may be stacked to alternate with each other in the vertical direction. Here, at least portions of the plurality of openings 21h, 22h, and 23h of the respective porous conductor layers 21, 22, and 23 may be connected to each other in the vertical direction to form a plurality of pores 20h exposing at least a portion of a surface of the base layer 10, such that water steam may be discharged, and thus, the delamination problem of the shielding film in a high-temperature process may be solved. Since the conductive mesh structures and the openings of the porous conductor layers 21, 22, and 23 may be distributed in a random manner, the conductive mesh structures (or the openings) of one of the porous conductor layers 21, 22, and may not completely overlap with the conductive mesh structures (or the openings) of another of the porous conductor layers 21, 22, and 23 in the vertical direction. For example, portions of the plurality of openings 21h, 22h, and 23h of the respective porous conductor layers 21, 22, and 23 may be connected to each other in the vertical direction to form the plurality of pores 20h exposing at least the portion of the surface of the base layer 10. Such portions of the plurality of openings 21h, 22h, and 23h of the respective porous conductor layers 21, 22, and 23 may have different sizes from each other. Portions of the plurality of openings 21h, 22h, and 23h of the respective porous conductor layers 21, 22, and 23 may be offset from each other in the vertical direction but connected to each other in the vertical direction to form the plurality of pores 20h exposing at least the portion of a surface of the base layer 10. Portions of the conductive mesh structures of one of the porous conductor layers 21, 22, and 23 may partially overlap with, or partially offset from, portions of the conductive mesh structures of another of the porous conductor layers 21, 22, and 23 in the vertical direction. Portions of the conductive mesh structures of one of the porous conductor layers 21, 22, and 23 may extend over portions of the plurality of openings 21h, 22h, and 23h of another of the porous conductor layers 21, 22, and 23. Particularly, the electromagnetic interference shielding layer 30A may be formed of a self-alignable nanoparticle coating solution, for example, a silver nanoparticle coating solution. Therefore, a conductive mesh may be rapidly and easily formed. Further, the number, a size, and a thickness of the pores 20h may be adjusted in accordance with electromagnetic interference shielding specifications by repeatedly forming the conductive mesh structures as described above in layers. Further, a conductive mesh having a large area may also be formed by a coating method. In addition, since a low-viscosity spray coating method may also be used, the shielding layer may even be formed on an inclined surface or a side surface.

Hereinafter, each configuration included in the electromagnetic interference shielding structure 50A according to the exemplary embodiment will be described in more detail.

The base layer 10 may be used as a substrate layer for forming the electromagnetic interference shielding layer 30A. A material of the base layer 10 is not particularly limited. That is, the base layer 10 may have various materials depending on a component to which electromagnetic shielding structure 50A is applied. For example, when the electromagnetic interference layer 30A is applied to a semiconductor package, the base layer 10 may be a molding material or encapsulant. In this case, the base layer 10 may contain an insulating resin such as an epoxy. However, the material of the base layer 10 is not limited thereto, but may be a different kind of insulating material.

The electromagnetic interference shielding layer 30A may serve to substantially shield electromagnetic interferences. The electromagnetic interference shielding layer 30A may include the plurality of porous conductor layers 21, 22, and 23. The porous conductor layers 21, 22, and 23 may have a porous structure having a plurality of openings 21h, 22h, and 23h, respectively. That is, each of the porous conductor layers 21, 22, and 23 may have a conductive mesh structure. The porous conductor layers 21, 22, and 23 may be stacked to alternate with each other in the vertical direction. The porous conductor layers 21, 22, and 23 may be stacked to alternate with each other in the vertical direction to form the porous structure 20 having a plurality of pores 20h. At least portions of the plurality of openings 21h, 22h, and 23h of the respective porous conductor layers 21, 22, and 23 may be connected to each other in the vertical direction to form a plurality of pores 20h at least partially exposing a surface of the base layer 10, such that water steam may be discharged, and thus, the delamination problem of the shielding film at a high-temperature process may be solved.

Each of the porous conductor layers 21, 22, and 23 of the electromagnetic interference shielding layer 30A may be formed of the self-alignable nanoparticle coating solution, for example, the silver nanoparticle coating solution. The nanoparticle coating solution may contain metal nanoparticles and a binder resin. As the metal nanoparticles, nanoparticles formed of silver, a silver-copper alloy, a silver-palladium alloy, or other silver alloy nanoparticles may be used, but the metal nanoparticles are not limited thereto. Nanoparticles formed of another metal may also be used. As the binder resin, an insulating resin known in the art such as an acrylic resin or an epoxy resin may be used. The nanoparticle coating solution may further contain other additives such as a surfactant and a solvent in addition to the metal nanoparticles and the binder resin. As a coating method, a coating method selected from a spray coating method, a spin coating method, a slit coating method, or other suitable coating methods may be used. The conductive mesh may be rapidly and easily formed by using the nanoparticle coating solution as described above. Further, the number, the size, and the thickness of the pores 20h may be adjusted in accordance with electromagnetic interference shielding specifications by repeatedly forming the porous conductor layers 21, 22, and 23 having the conductive mesh structures as described above in layers. Further, a conductive mesh having a large area may also be formed using the coating method. In addition, since a low-viscosity spray coating method may also be used, the shielding layer 30A may even be formed on an inclined surface or a side surface of the base layer 10.

The number of porous conductor layers 21, 22, and 23 of the electromagnetic interference shielding layer 30A is not particularly limited. The number of porous conductor layers may be larger or smaller than depicted in the accompanying drawings. Further, the size or the number of pores 20h implemented by forming the porous conductor layers 21, 22, and 23 in layers are not particularly limited, and may be controlled in accordance with the electromagnetic interference shielding specification.

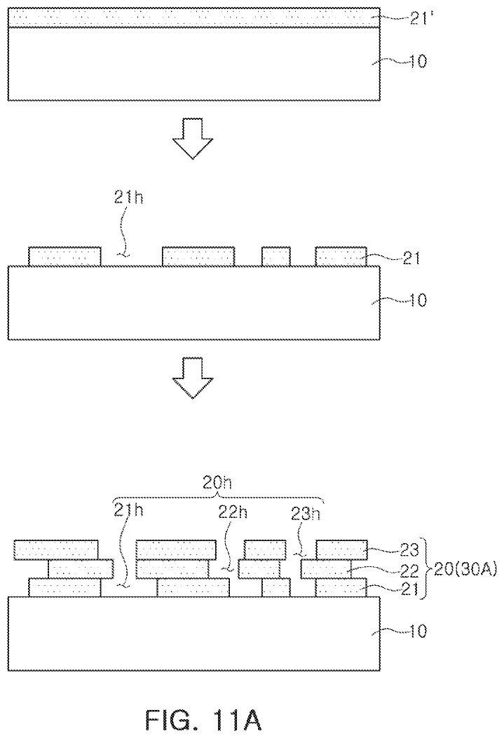

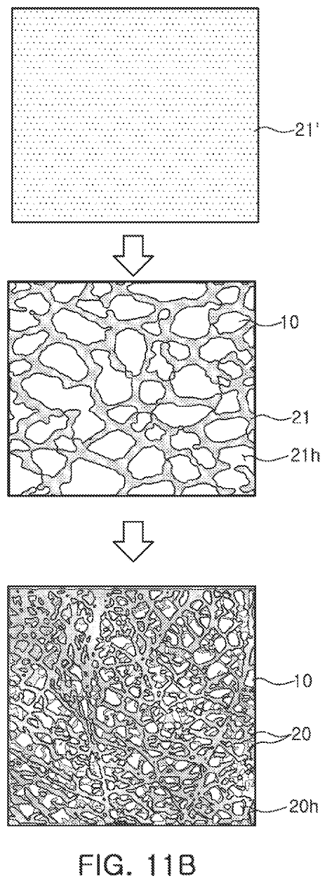

FIGS. 11A and 11B are schematic views illustrating an example of a manufacturing method of the electromagnetic interference shielding structure of FIG. 9. FIG. 11A is a cross-sectional view illustrating the manufacturing method, and FIG. 11B is a plan view illustrating the manufacturing method.

Referring to FIGS. 11A and 11B, first, a nanoparticle coating layer 21′ may be formed on the base layer 10. The nanoparticle coating layer 21′ may be formed by coating the nanoparticle coating solution containing the metal nanoparticles and the binder resin by a method known in the art such as a spray coating method, a spin coating method, a slit coating method, or the like. Next, a first porous conductor layer 21 having a conductive mesh structure with a plurality of first openings 21h may be formed using self-alignment of the metal nanoparticles. Next, a second porous conductor layer 22 having a conductive mesh structure with a plurality of second openings 22h and a third porous conductor layer 23 having a conductive mesh structure with a plurality of third openings 23h may be formed by repeating the coating of the nanoparticle coating solution on the first porous conductor layer 21 and the self-alignment of the metal nanoparticles. If necessary, a larger number of porous conductor layers may also be formed by repeating the above-mentioned procedure. As a result, the porous structure 20 having a denser mesh structure with a plurality of pores 20h, that is, the electromagnetic interference shielding layer 30A according to the exemplary embodiment may be formed.

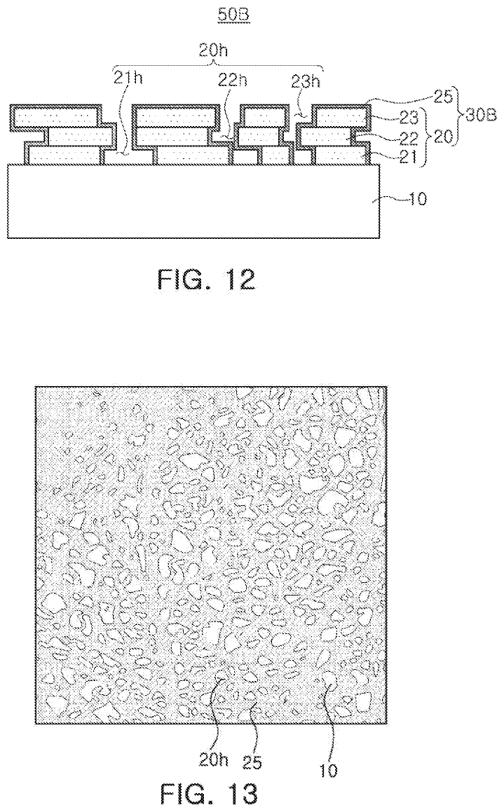

FIG. 12 is a schematic cross-sectional view illustrating another example of an electromagnetic interference shielding structure.

FIG. 13 is a schematic plan view of the electromagnetic interference shielding structure of FIG. 12 when viewed from the top.

Referring to FIGS. 12 and 13, in an electromagnetic interference shielding structure 50B according to another exemplary embodiment, an electromagnetic interference shielding layer 30B may further include a metal film 25 covering outer surfaces of respective porous conductor layers 21, 22, and 23, that is, an outer surface of a porous structure 20. The metal film 25 may be formed by a plating method, for example, an electroplating method using the porous structure 20 as a seed layer. The metal film 25 may contain a metal material known to be used in plating in the art such as copper. A size of pores 20h of the porous structure 20 may be controlled by controlling a plating thickness of the metal film 25, and as a result, an electromagnetic interference shielding effect may be significantly increased. Since other contents, except for the above-mentioned feature, are substantially the same as described above, a detailed description thereof will be omitted.

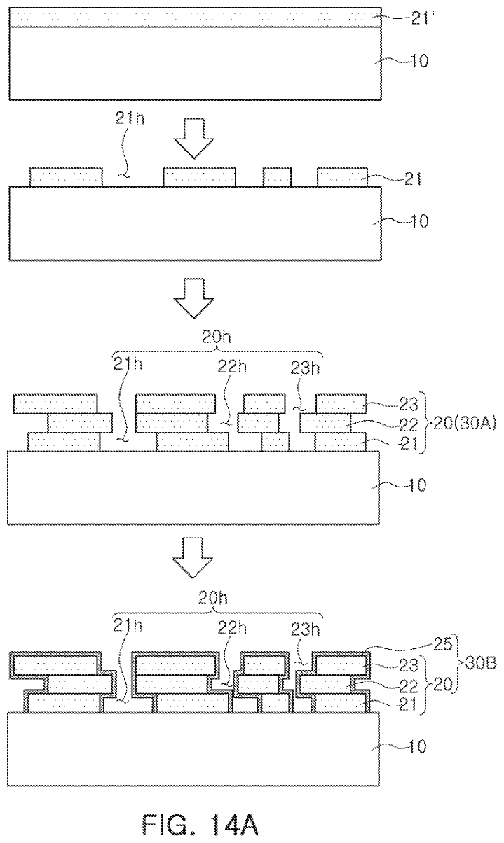

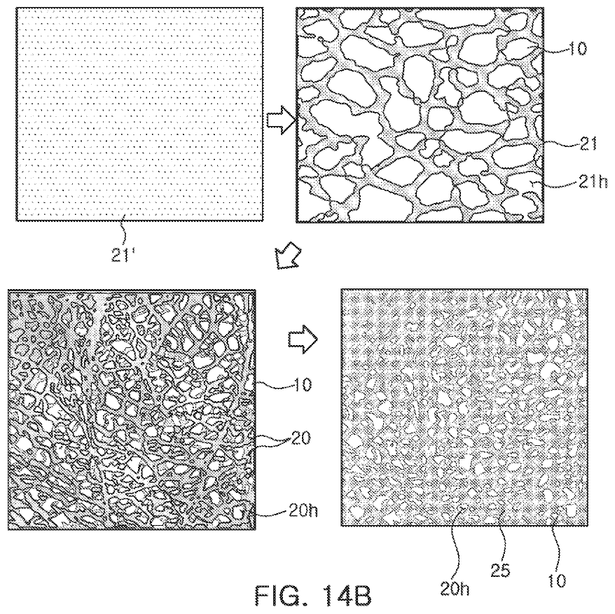

FIGS. 14A and 14B are schematic views illustrating an example of a manufacturing method of the electromagnetic interference shielding structure of FIG. 12. FIG. 14A is a cross-sectional view illustrating the manufacturing method, and FIG. 14B is a plan view illustrating the manufacturing method.

Referring to FIGS. 14A and 14B, first, a nanoparticle coating layer 21′ may be formed on the base layer 10. Next, a first porous conductor layer 21 having a conductive mesh structure with a plurality of first openings 21h may be formed using self-alignment of the metal nanoparticles. Next, a second porous conductor layer 22 having a conductive mesh structure with a plurality of second openings 22h and a third porous conductor layer 23 having a conductive mesh structure with a plurality of third openings 23h may be formed by repeating the coating of the nanoparticle coating solution on the first porous conductor layer 21 and the self-alignment of the metal nanoparticles. Next, the metal film 25 may be formed by using the formed porous structure 20 having the mesh structure as the seed layer and performing a plating method known in the art such as an electroplating method thereon. As a result, the electromagnetic interference shielding layer 30B according to another exemplary embodiment may be formed. Since other contents except for the above-mentioned feature are substantially the same as described above, a detailed description thereof will be omitted.

Hereinafter, a semiconductor package to which the above-mentioned electromagnetic interference shielding structure is applied will be described with reference to the accompanying drawings.

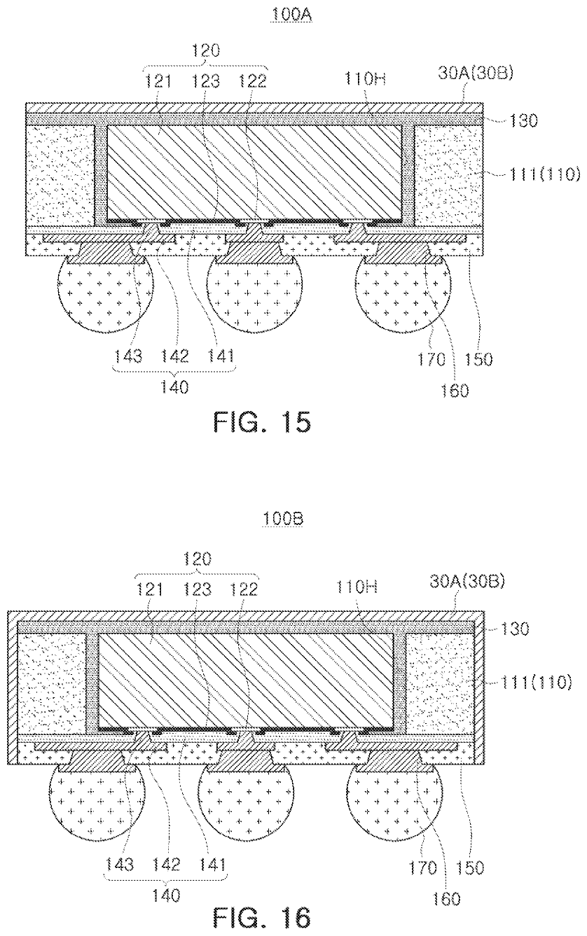

FIG. 15 is a schematic cross-sectional view illustrating an example of a semiconductor package.

Referring to FIG. 15, a fan-out semiconductor package 100A according to an exemplary embodiment may include a core member 110 having a through-hole 110H, a semiconductor chip 120 disposed in the through-hole 110H of the core member 110 and having an active surface on which connection pads 122 are disposed and an inactive surface opposing the active surface, an encapsulant 130 encapsulating the semiconductor chip 120 and covering at least a portion of the through-hole 110H, a connection member 140 disposed on the core member 110 and the active surface of the semiconductor chip 120, a passivation layer 150 disposed on the connection member 140, underbump metals 160 disposed on openings 151 of the passivation layer 150, and electrical connection structures 170 disposed on the passivation layer 150 and connected to the underbump metals 160. Particularly, the fan-out semiconductor package 100A according to the exemplary embodiment may include an electromagnetic interference shielding layer 30A or 30B disposed on the encapsulant 130 and covering the inactive surface of the semiconductor ship 120. The electromagnetic interference shielding layer 30A or 30B may effectively shield electromagnetic interference generated by the semiconductor chip 120 or introduced into the semiconductor chip 120 from the outside.

The core member 110 may further improve rigidity of the fan-out semiconductor package 100A depending on a specific material thereof, and perform a role of securing uniformity in thickness of the encapsulant 130, and the like. The core member 110 may have the through-hole 110H. The semiconductor chip 120 may be disposed in the through-hole 110H to be spaced apart from the core member 110 by a predetermined distance. Side surfaces of the semiconductor chip 120 may be surrounded by the core member 110. However, such a form is only an example and may be variously modified to have other forms, and the core member 110 may perform another function depending on such a form. If necessary, the core member 110 may be omitted.

The core member 110 may include an insulating layer 111. An insulating material may be used as a material of the insulating layer 111. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, an ajinomoto build-up film (ABF), FR-4, bismaleimide triazine (BT), or the like. In a case of using a material having high rigidity such as the prepreg containing a glass fiber, or the like, the core member 110 may also be used as a support member for controlling warpage of the fan-out semiconductor package 100A.

The semiconductor chip 120 may be an integrated circuit (IC) provided in an amount of several hundred to several million or more elements integrated in a single chip. In this case, the IC may be, for example, a processor chip (more specifically, an application processor (AP)) such as a central processor (for example, a CPU), a graphic processor (for example, a GPU), a field programmable gate array (FPGA), a digital signal processor, a cryptographic processor, a micro processor, a micro controller, or the like. However, the IC is not limited thereto, but may also be a logic chip such as an analog-to-digital converter, an application-specific IC (ASIC), or the like or a memory chip such as a volatile memory (for example, a dynamic random access memory (DRAM)), a non-volatile memory (for example, a read only memory (ROM)), a flash memory, or the like. Further, a combination of these integrated circuits may be disposed.

The semiconductor chip 120 may be formed on the basis of an active wafer. In this case, a base material of a body 121 of the semiconductor chip 120 may be silicon (Si), germanium (Ge), gallium arsenide (GaAs), or the like. Various circuits may be formed on the body 121. The connection pad 122 may electrically connect the semiconductor chip 120 to other components. As a material of the connection pad 122, a conductive material such as aluminum (Al), or the like, may be used without a particular limitation. A passivation film 123 exposing the connection pads 122 may be formed on the body 121, and may be an oxide film, a nitride film, or the like, or a double layer of an oxide film and a nitride film. A lower surface of the connection pad 122 may have a step with respect to a lower surface of the encapsulant 130 through the passivation film 123, thereby making it possible to prevent the encapsulant 130 from bleeding to the lower surface of the connection pad 122. An insulating film (not illustrated), and the like, may also be further disposed in other required positions. However, the semiconductor chip 120 may be a bare die, but if necessary, a redistribution layer (not illustrated) may further be formed on the active surface of the semiconductor chip 120, and a bump (not illustrated), or the like, may be connected to the connection pad 122.

The encapsulant 130 may protect the core member 110, the semiconductor chip 120, and the like. An encapsulation form of the encapsulant 130 is not particularly limited, but may be a form in which the encapsulant 130 surrounds at least portions of the core member 110, the semiconductor chip 120, and the like. For example, the encapsulant 130 may cover the core member 110 and the inactive surface of the semiconductor chip 120 and fill a space between a side wall of the through-hole 110H and a side surface of the semiconductor chip 120. Further, the encapsulant 130 may fill at least a portion of a space between the passivation film 123 of the semiconductor chip 120 and the connection member 140. Meanwhile, the encapsulant 130 may fill the through-hole 110H to thus serve as an adhesive and reduce buckling of the semiconductor chip 120 depending on certain materials.

A material of the encapsulant 130 is not particularly limited. For example, an insulating material may be used as the material of the encapsulant 130. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. If necessary, a PID resin may also be used as the insulating material.

The electromagnetic interference shielding layer 30A or 30B may include a porous structure 20 or include a porous structure 20 and a metal film 25, as described above. The electromagnetic interference shielding layer 30A or 30B may be formed on an upper surface of the encapsulant 130 used as a base layer to cover the inactive surface of the semiconductor chip 120. Since the electromagnetic interference shielding layer 30A or 30B is substantially the same as described above, a detailed description thereof will be omitted.

The connection member 140 may redistribute the connection pads 122 of the semiconductor chip 120. Several tens to several hundreds of connection pads 122 of the semiconductor chip 120 having various functions may be redistributed by the connection member 140, and may be physically and/or electrically connected to the outside through the electrical connection structures 170 depending on its functions. The connection member 140 may include insulating layers 141 disposed on the core member 110 and the active surface of the semiconductor chip 120, redistribution layers 142 disposed on the insulating layers 141, and connection vias 143 penetrating through the insulating layers 141 and electrically connecting the connection pads 122 of the semiconductor chip 120 and the redistribution layers 142 to each other. The insulating layers 141, the redistribution layers 142, and the connection vias 143 of the connection member 140 may be implemented in a larger number of layers that the number of layers illustrated in the accompanying drawings.

A material of each of the insulating layers 141 may be an insulating material. In this case, a photosensitive insulating material such as a PID resin as well as the above-mentioned insulating material may also be used as the insulating material. That is, each of the insulating layers 141 may be a photosensitive insulating layer. When the insulating layer 141 has photosensitive properties, the insulating layer 141 may be formed to have a thinner thickness, and a fine pitch of the connection via 143 may be achieved more easily. Each of the insulating layers 141 may be a photosensitive insulating layer including an insulating resin and an inorganic filler. When the insulating layers 141 are multiple layers, materials of the insulating layers 141 may be the same as each other, and may also be different from each other, if necessary. When the insulating layers 141 are the multiple layers, the insulating layers may be integrated with each other depending on a process, such that a boundary therebetween may also not be apparent.

The redistribution layers 142 may substantially serve to redistribute the connection pads 122. A material of the redistribution layer 142 may be a conductive material such as copper (Cu), aluminum (Al), silver (Ag), tin (Sn), gold (Au), nickel (Ni), lead (Pb), titanium (Ti), or alloys thereof. The redistribution layers 142 may perform various functions depending on designs of corresponding layers. For example, the redistribution layers 142 may include ground

(GND) patterns, power (PWR) patterns, signal (S) patterns, and the like. Here, the signal (S) patterns may include various signals except for the ground (GND) patterns, the power (PWR) patterns, and the like, such as data signals, and the like. Further, the redistribution layers 142 may include via pad patterns, electrical connection structure pad patterns, and the like.

The connection vias 143 may electrically connect the redistribution layers 142, the connection pads 122, and the like, formed on different layers to each other, thereby resulting in an electrical path in the fan-out semiconductor package 100A. A material of each of the connection vias 143 may be a conductive material such as copper (Cu), aluminum (Al), silver (Ag), tin (Sn), gold (Au), nickel (Ni), lead (Pb), titanium (Ti), or alloys thereof. Each of the connection vias 143 may be completely filled with the conductive material, or the conductive material may also be formed along a wall of each of via holes. Further, the connection vias 143 may have any shape known in the art such as a tapered shape, a cylindrical shape, and the like.

The passivation layer 150 may protect the connection member 140 from external physical or chemical damage, or the like. The passivation layer 150 may have openings 151 exposing at least portions of the redistribution layers 142 of the connection member 140. The number of openings 151 formed in the passivation layer 150 may be several tens to several thousands. A material of the passivation layer 150 is not particularly limited. For example, an insulating material may be used as the material of the passivation layer 150. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used.

The underbump metals 160 may improve connection reliability of the electrical connection structures 170, thereby improving board level reliability of the fan-out semiconductor package 100A. The underbump metals 160 may be connected to the redistribution layers 142 of the connection member 140 exposed through the openings 151 of the passivation layer 150. The underbump metals 160 may be formed in the openings 151 of the passivation layer 150 by a metallization method known in the art using a conductive material known in the art such as a metal, but is not limited thereto.

The electrical connection structure 170 may physically and/or electrically connect the fan-out semiconductor package 100A to the outside. For example, the fan-out semiconductor package 100A may be mounted on a mainboard of an electronic device through the electrical connection structure 170. Each of the electrical connection structures 170 may be formed of a conductive material, for example, a solder, or the like. However, this is only an example, and a material of each of the electrical connection structures 170 is not particularly limited thereto. Each of the electrical connection structures 170 may be a land, a ball, a pin, or the like. The electrical connection structures 170 may be formed as a multilayer or single layer structure. When the electrical connection structures 170 are formed as a multilayer structure, the electrical connection structures 170 may include a copper (Cu) pillar and a solder. When the electrical connection structures 170 are formed as a single layer structure, the electrical connection structures 170 may include a tin-silver solder or copper (Cu). However, this is only an example, and the electrical connection structures 170 are not limited thereto.

The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several thousands according to the number of connection pads 122, or may be provided in an amount of several tens to several thousands or more or several tens to several thousands or less. When the electrical connection structures 170 are solder balls, the electrical connection structures 170 may cover side surfaces of the underbump metals 160 extending onto one surface of the passivation layer 150, and connection reliability may be more excellent.

At least one of the electrical connection structures 170 may be disposed in a fan-out region. The fan-out region refers to a region except for a region in which the semiconductor chip 120 is disposed. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be manufactured to have a small thickness, and may have price competitiveness.

Meanwhile, although not illustrated, if necessary, a metal thin film may be formed for dissipating heat and/or shielding electromagnetic interference may be formed on a wall surface of the through-hole 110H. Further, if necessary, a plurality of semiconductor chips 120 performing functions that are the same as or different from each other may be disposed in the through-hole 110H. In addition, if necessary, a separate passive component such as an inductor, a capacitor, or the like, may be disposed in the through-hole 110H. Further, if necessary, a surface mount technology (SMT) component including a passive component such as an inductor, a capacitor, or the like, may be disposed on a surface of the passivation layer 150.

FIG. 16 is a schematic cross-sectional view illustrating another example of the semiconductor package.

Referring to FIG. 16, in a semiconductor package 100B according to another exemplary embodiment, an electromagnetic interference shielding layer 30A or 30B may cover an outer side surface of an encapsulant 130, an outer side surface of a core member 110, and an outer side surface of a connection member 140 as well as an upper surface of the encapsulant 130. As described above, the electromagnetic interference shielding layer 30A or 30B may be formed by a spray coating method, such that the electromagnetic interference shielding layer 30A or 30B may be formed on an inclined surface or a side surface. Since other contents except for the above-mentioned feature are substantially the same as described above, a detailed description thereof will be omitted.

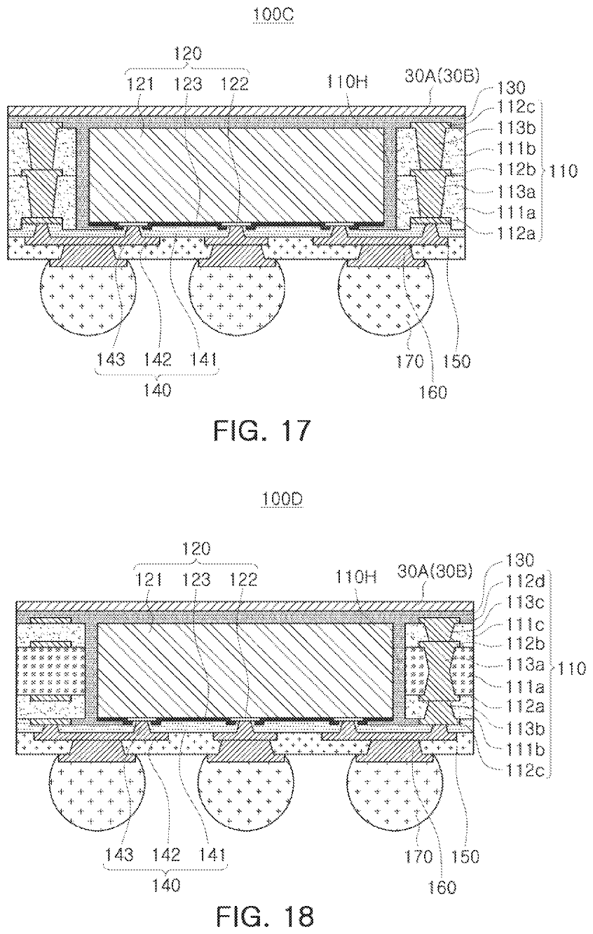

FIG. 17 is a schematic cross-sectional view illustrating another example of the semiconductor package.

Referring to FIG. 17, in a fan-out semiconductor package 100C according to another exemplary embodiment, a core member 110 may include a first insulating layer 111a coming in contact with a connection member 140, a first wiring layer 112a coming in contact with the connection member 140 and embedded in the first insulating layer 111a, a second wiring layer 112b disposed on the other surface of the first insulating layer 111a opposing one surface of the first insulating layer 111a in which the first wiring layer 112a is embedded, a second insulating layer 111b disposed on the first insulating layer 111a and covering the second wiring layer 112b, and a third wiring layer 112c disposed on the second insulating layer 111b. The first to third wiring layers 112a, 112b, and 112c may be electrically connected to connection pads 122. The first and second wiring layers 112a and 112b may be electrically connected to each other through a first connection via 113a penetrating through the first insulating layer 111a, and the second and third wiring layers 112b and 112c may be electrically connected to each other through a second connection via 113b penetrating through the second insulating layer 111b.

A material of the insulating layers 111a and 111b is not particularly limited. For example, an insulating material may be used as the material of the insulating layers 111a and 111b. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. If necessary, a PID resin may also be used as the insulating material.

The wiring layers 112a, 112b, and 112c may serve to redistribute the connection pads 122 of the semiconductor chip 120. A material of the wiring layers 112a, 112b, and 112c may be a conductive material such as copper (Cu), aluminum (Al), silver (Ag), tin (Sn), gold (Au), nickel (Ni), lead (Pb), titanium (Ti), or alloys thereof. The wiring layers 112a, 112b, and 112c may perform various functions depending on designs of corresponding layers. For example, the wiring layers 112a, 112b, and 112c may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. Further, the wiring layers 112a, 112b, and 112c may include via pads, wire pads, electrical connection structure pads, and the like.

When the first wiring layer 112a is embedded in the first insulating layer 111a, a step generated by a thickness of the first wiring layer 112a may be significantly decreased, such that an insulation distance of the connection member 140 may become constant. That is, a difference between a distance from a redistribution layer 142 to a lower surface of the first insulating layer 111a and a distance from the redistribution layer 142 to the connection pad 122 of the semiconductor chip 120 may be smaller than a thickness of the first wiring layer 112a. Therefore, it may be easy to design a high-density wiring of the connection member 140.

A lower surface of the first wiring layer 112a may be positioned on a level above a lower surface of the connection pad 122. Further, a distance between the redistribution layer 142 and the first wiring layer 112a may be greater than a distance between the redistribution layer 142 and the connection pad 122. The reason may be that the first wiring layer 112a may be recessed in the insulating layer 111. When the first wiring layer 112a is recessed in the first insulating layer to have a step between the lower surface of the first insulating layer 111a and the lower surface of the first wiring layer 112a as described above, contamination of the first wiring layer 112a by bleeding of a material of an encapsulant 130 may be prevented. The second wiring layer 112b may be positioned between the active surface and the inactive surface of the semiconductor chip 120. The core member 110 may be formed to have a thickness corresponding to a thickness of the semiconductor chip 120, and thus, the second wiring layer 112b formed in the core member 110 may be disposed on a level between the active surface and the inactive surface of the semiconductor chip 120.

The connection vias 113a and 113b may electrically connect the wiring layers 112a, 112b, and 112c disposed in different layers to each other, thereby forming an electrical path in the core member 110. The connection vias 113a and 113b may also be formed of a conductive material. Each of the connection vias 113a and 113b may be completely filled with the conductive material, or the conductive material may also be formed along a wall of each of the connection via holes. Each of the connection vias 113a and 113b may have a tapered shape.

At the time of forming a hole for the first connection via 113a, a portion of a pad pattern of the first wiring layer 112a may serve as a stopper. Therefore, the first connection via 113a has a tapered shape so that a width of an upper surface thereof is greater than that of a lower surface thereof, which is advantageous in view of a process. In this case, the first connection via 113a may be integrated with a pad pattern of the second wiring layer 112b. Further, at the time of forming a hole for the second connection via 113b, a portion of the pad pattern of the second wiring layer 112b may serve as a stopper. Therefore, the second connection via 113b has a tapered shape so that a width of an upper surface thereof is greater than that of a lower surface thereof, which is advantageous in view of a process. In this case, the second connection via 113b may be integrated with a pad pattern of the third wiring layer 112c.

Since other contents, for example, the electromagnetic interference shielding layer 30A or 30B, and the like, except for the above-mentioned feature are substantially the same as described above, a detailed description thereof will be omitted. The electromagnetic interference shielding layer 30A or 30B may cover an outer side surface of an encapsulant 130, an outer side surface of a core member 110, and an outer side surface of a connection member 140 as well as an upper surface of the encapsulant 130.

FIG. 18 is a schematic cross-sectional view illustrating another example of the semiconductor package.

Referring to FIG. 18, in a fan-out semiconductor package 100D according to another exemplary embodiment, a core member 110 may include a first insulating layer 111a, first and second wiring layers 112a and 112b disposed on both surfaces of the first insulating layer 111a, a second insulating layer 111b disposed on the first insulating layer 111a and covering the first wiring layer 112a, a third wiring layer 112c disposed on the second insulating layer 111b, a third insulating layer 111c disposed on the first insulating layer 111a and covering the second wiring layer 112b, and a fourth wiring layer 112d disposed on the third insulating layer 111c. The first to fourth wiring layers 112a, 112b, 112c, and 112d may be electrically connected to connection pads 122. Since the core member 110 may include a large number of wiring layers 112a, 112b, 112c, and 112d, a connection member 140 may be further simplified. Therefore, a decrease in a yield depending on a defect occurring in a process of forming the connection member 140 may be suppressed. Meanwhile, the first to fourth wiring layers 112a, 112b, 112c, and 112d may be electrically connected to each other through first to third connection vias 113a, 113b, and 113c respectively penetrating through the first to third insulating layers 111a, 111b, and 111c.

A material of the insulating layers 111a to 111c is not particularly limited. For example, an insulating material may be used as the material of the insulating layers 111a, 111b, and 111c. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. If necessary, a PID resin may also be used as the insulating material.

The first insulating layer 111a may have a thickness greater than those of the second and third insulating layers 111b and 111c. The first insulating layer 111a may be basically relatively thick in order to maintain rigidity, and the second and third insulating layers 111b and 111c may be introduced in order to form a larger number of wiring layers 112c and 112d. The first insulating layer 111a may include an insulating material different from those of the second and third insulating layers 111b and 111c. For example, the first insulating layer 111a may be, for example, prepreg including a glass fiber, a filler, and an insulating resin, and each of the second and third insulating layers 111b and 111c may be an ABF or PID film including an inorganic filler and an insulating resin. However, the materials of the first insulating layer 111a and the second and third insulating layers 111b and 111c are not limited thereto.

The wiring layers 112a, 112b, 112c, and 112d may serve to redistribute the connection pads 122 of the semiconductor chip 120. A material of the wiring layers 112a, 112b, 112c, and 112d may be a conductive material such as copper (Cu), aluminum (Al), silver (Ag), tin (Sn), gold (Au), nickel (Ni), lead (Pb), titanium (Ti), or alloys thereof. The wiring layers 112a, 112b, 112c, and 112d may perform various functions depending on designs of corresponding layers. For example, the wiring layers 112a, 112b, 112c, and 112d may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. Further, the wiring layers 112a, 112b, 112c, and 112d may include via pads, wire pads, electrical connection structure pads, and the like.

A lower surface of the third wiring layer 112c may be positioned on a level below a lower surface of the connection pad 122. Further, a distance between the redistribution layer 142 and the third wiring layer 112c may be smaller than a distance between the redistribution layer 142 and the connection pad 122. The reason is that the third wiring layer 112c may be disposed on the second insulating layer 111b in a protruding form, resulting in coming in contact with the connection member 140. The first and second wiring layers 112a and 112b may be disposed between an active surface and an inactive surface of the semiconductor chip 120.

The connection vias 113a, 113b, and 113c may electrically connect the wiring layers 112a, 112b, 112c, and 112d disposed in different layers to each other, thereby forming an electrical path in the core member 110. The connection vias 113a, 113b, and 113c may also be formed of a conductive material. Each of the connection vias 113a, 113b, and 113c may be completely filled with the conductive material, or the conductive material may also be formed along a wall of each of the connection via holes. The first connection via 113a may have a cylindrical shape or hourglass shape, and the second and third connection vias 113b and 113c may have tapered shapes of which directions are opposite to each other. The first connection via 113a penetrating through the first insulating layer 111a may have a diameter greater than those of the second and third connection vias 113b and 113c respectively penetrating through the second and third insulating layers 111b and 111c.

Since other contents, for example, the electromagnetic interference shielding layer 30A or 30B, and the like, except for the above-mentioned feature are substantially the same as described above, a detailed description thereof will be omitted. The electromagnetic interference shielding layer 30A or 30B may cover an outer side surface of an encapsulant 130, an outer side surface of a core member 110, and an outer side surface of a connection member 140 as well as an upper surface of the encapsulant 130.

Meanwhile, the electromagnetic interference shielding structures 50A and 50B described in the present disclosure may be applied to various types of semiconductor packages having different structures as well as the above-mentioned semiconductor packages 100A, 100B, 100C, and 100D. For example, the electromagnetic interference shielding structures 50A and 50B may also be applied onto an epoxy molding compound (EMC) of a package in which a semiconductor chip or various components are simply molded using the EMC. Further, the electromagnetic interference shielding structures 50A and 50B may also be applied to various components or substrates requiring electromagnetic interference shielding in addition to the semiconductor package.

As set forth above, according to exemplary embodiments in the present disclosure, the electromagnetic interference shielding structure capable of solving the delamination problem of the shielding film, adjusting the size and the thickness of the pores, forming a large-area conductive mesh by using a coating method, and being formed even on an inclined surface or a side surface by a low-viscosity spray coating, and the semiconductor package including the same.

Herein, a lower side, a lower portion, a lower surface, and the like, are used to refer to a downward direction in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above, and concepts of the term “upper/lower” may be changed any time.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

While exemplary embodiments have been shown and described above, it will be apparent to those skilled in the art that modifications and variations could be made without departing from the scope of the present invention as defined by the appended claims.

What is claimed is:

1. An electromagnetic interference shielding structure comprising:
a base layer; and
an electromagnetic interference shielding layer disposed on the base layer,
wherein the electromagnetic shielding layer includes a plurality of porous conductor layers,
each of the porous conductor layers has a plurality of openings, and
the porous conductor layers are stacked on each other in a stacking direction.

2. The electromagnetic interference shielding structure of claim 1, wherein at least portions of the plurality of openings of each of the porous conductor layers are connected to each other in the stacking direction to expose at least portions of a surface of the base layer.

3. The electromagnetic interference shielding structure of claim 1, wherein each of the porous conductor layers has a conductive mesh structure.

4. The electromagnetic interference shielding structure of claim 3, wherein each of the porous conductor layers contains self-aligned silver nanoparticles.

5. The electromagnetic interference shielding structure of claim 3, wherein the conductive mesh structure of one of the plurality of porous conductor layers and the conductive mesh structure of another of the plurality of porous conductor layers are partially offset from each other in the stacking direction.

6. The electromagnetic interference shielding structure of claim 3, wherein the conductive mesh structure of one of the plurality of porous conductor layers extends over one of plurality of openings of another of the plurality of porous conductor layers.

7. The electromagnetic interference shielding structure of claim 1, wherein the electromagnetic interference shielding layer further includes a metal film covering an outer surface of each of the porous conductor layers.

8. The electromagnetic interference shielding structure of claim 7, wherein the metal film contains copper.

9. The electromagnetic interference shielding structure of claim 1, wherein the plurality of openings of each of the plurality of porous conductor layers are randomly distributed.

10. A semiconductor package comprising:
a connection member having redistribution layers;
a semiconductor chip disposed on a connection member and having an active surface on which connection pads electrically connected to the redistribution layers are disposed and an inactive surface opposing the active surface;
an encapsulant disposed on the connection member and encapsulating the semiconductor chip; and
an electromagnetic interference shielding layer disposed on the encapsulant,
wherein the electromagnetic shielding layer includes a plurality of porous conductor layers,
each of the porous conductor layers has a plurality of openings, and
the porous conductor layers are stacked on each other in a stacking direction.

11. The semiconductor package of claim 10, wherein at least portions of the plurality of openings of each of the porous conductor layers are connected to each other in the stacking direction to expose at least portions of a surface of the encapsulant.

12. The semiconductor package of claim 10, wherein each of the porous conductor layers has a conductive mesh structure.

13. The semiconductor package of claim 12, wherein each of the porous conductor layers contains self-aligned silver nanoparticles.

14. The semiconductor package of claim 10, wherein the electromagnetic interference shielding layer further includes a metal film covering an outer surface of each of the porous conductor layers.

15. The semiconductor package of claim 14, wherein the metal film contains copper.

16. The semiconductor package of claim 10, wherein the electromagnetic interference shielding layer covers an upper surface of the encapsulant.

17. The semiconductor package of claim 16, wherein the electromagnetic interference shielding layer also covers a side surface of the encapsulant and a side surface of the connection member.

18. The semiconductor package of claim 10, further comprising a core member disposed on the connection member and having a through-hole,
wherein the semiconductor chip is disposed in the through-hole of the core member.

19. The semiconductor package of claim 18, wherein the core member includes one or more wiring layers electrically connected to the connection pads of the semiconductor chip.

20. The semiconductor package of claim 10, wherein the plurality of openings of each of the plurality of porous conductor layers are randomly distributed.
